(19) United States
(12) Patent Application Publication
(10) Pub. No.: US 2025/0185188 A1
(43) Pub. Date: Jun. 5, 2025

(54) BLOCKING ACCESS TO HIGH TEMPERATURE COMPONENTS

(71) Applicant: INTERNATIONAL BUSINESS MACHINES CORPORATION, ARMONK, NY (US)

(72) Inventors: JOHN S. WERNER, FISHKILL, NY (US); ARKADIY O. TSFASMAN, WAPPINGERS FALLS, NY (US); ROBERT WALSH, WALLKILL, NY (US)

(21) Appl. No.: 18/525,962

(22) Filed: Dec. 1, 2023

(51) Int. Cl. H05K 5/02

(52) U.S. Cl. CPC H05K 5/0208; H05K 5/0209; H05K 5/0221

(57) ABSTRACT

Systems and apparatus for blocking access to high temperature components include a computer component, and a shape memory alloy (SMA) interlock thermally coupled to the computer component, wherein the SMA interlock is configured to prevent access to the computer component when a temperature of the computer component exceeds a threshold temperature.

### BACKGROUND

The present disclosure relates to methods and systems for blocking access to high temperature components.

### SUMMARY

Systems and apparatus for blocking access to high temperature components according to various embodiments are disclosed in this specification. In accordance with one aspect of the present disclosure, a system for blocking access to high temperature components may include a computer component, and a shape memory alloy (SMA) interlock thermally coupled to the computer component, wherein the SMA interlock is configured to prevent access to the computer component when a temperature of the computer component exceeds a threshold temperature.

In accordance with another aspect of the present disclosure, blocking access to high temperature components may include an apparatus including a cover configured to block access to a computer component, and an engaging component comprising a shape memory alloy (SMA) material, wherein the engaging component is configured to couple to the cover based on a temperature of the engaging component exceeding a threshold temperature.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a system configured for blocking access to high temperature components in accordance with embodiments of the present disclosure.

FIG. 2 shows an example line drawing of a system configured for blocking access to high temperature components in accordance with embodiments of the present disclosure.

FIG. 3 shows an example line drawing of a system configured for blocking access to high temperature components in accordance with embodiments of the present disclosure.

FIG. 4 shows an example line drawing of a system configured for blocking access to high temperature components in accordance with embodiments of the present disclosure.

### DETAILED DESCRIPTION

Computer components may get hot under normal use. Sometimes computer components may need to be removed or handled before they have completely cooled off. However, handling components that are too hot can lead to burns or other injuries, dropping the component, or otherwise damaging the component or other components in the system. Components may be locked or covered to prevent access; however, such locked components must be unlocked each time they are to be removed or accessed. The present disclosure describes embodiments configured to lock or cover components while they are hot but provide access to such components when they are at a safe temperature.

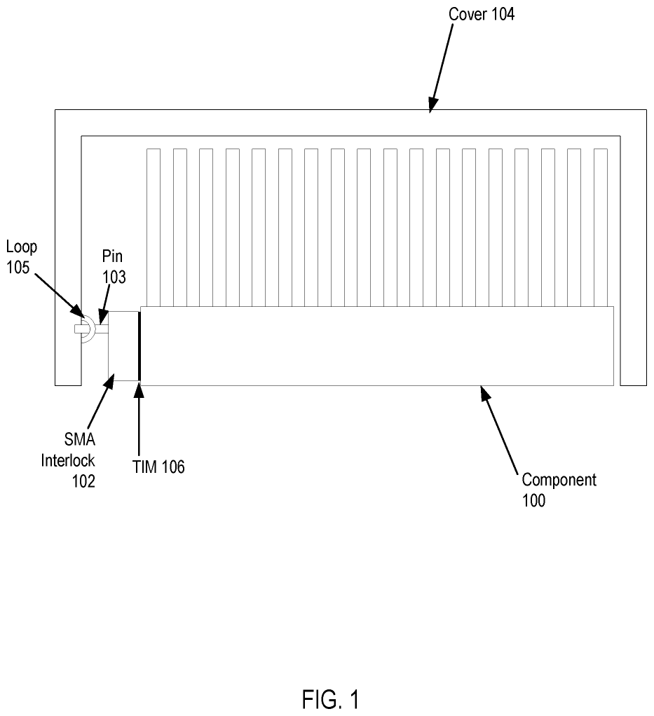

Exemplary methods, apparatus, and systems for blocking access to high temperature components in accordance with the present disclosure are described with reference to the accompanying drawings, beginning with FIG. 1. FIG. 1 sets forth an example line drawing of a system configured for blocking access to high temperature components in accordance with embodiments of the present disclosure. The example of FIG. 1 includes a component 100, a shape memory alloy (SMA) interlock 102, and a cover 104. As will be described in further detail below, the system of FIG. 1 is configured to lock the cover 104 in place over the component 100 when the temperature of the component 100 exceeds a temperature threshold, thereby preventing users from accessing the component whenever it is too hot to be safely handled.

The example component 100 in FIG. 1 is a heatsink component. However, in other embodiments, component 100 may be any other computing component, such as a server, memory, a chip, circuit board, cable, system, computing system, and the like. In the example system of FIG. 1, the SMA interlock 102 is coupled to the component 100. The SMA interlock 102 of FIG. 1 is thermally coupled to the heatsink (component 100) via a thermal interface material (TIM) 106. In other embodiments, the SMA interlock may be thermally coupled to the component without a TIM 106 and may be directly coupled to the component. For example, a TIM may be useful when the surface of the component that the SMA interlock 102 is coupled to is uneven or not flat. In one embodiment, the component 100 may be a cable connector that gets too hot to safely touch, and a TIM may be useful for thermally coupling the SMA interlock to the rounded surface of the cable connector.

In the example of FIG. 1, the cover 104 is positioned over the component 100 in order to block access to the component. For example, the cover, when positioned over the component (as shown here in FIG. 1), prevents a user from touching, servicing, or otherwise handling the component 100. The example cover 104 of FIG. 1 includes a loop 105. The cover 104 may be in the form of a solid plate, may include holes for ventilation, or may be in the form of a grate or grid or other patterned covering.

The example SMA interlock 102 of FIG. 1 includes a pin 103. The pin 103 is composed of an SMA material such that when the component is above a certain temperature threshold, the SMA material of the pin deforms and engages with the loop 105 to prohibit accessing the component behind the SMA interlock or cover. In another embodiment, one or more other parts of the SMA interlock may be composed of an SMA material. There may be one or more different SMA materials included within an SMA interlock. A shape memory alloy is an alloy that can be deformed when cold but returns to its pre-deformed, or “remembered”, shape when it is heated. The remembered shape may be configured through a heat-treatment process. Further, the temperature threshold at which an SMA returns to its remembered shape may be configurable based on the specific physical makeup of the SMA material. For example, a specific alloy may be selected for the SMA interlock in order to select the temperature threshold at which the SMA interlock will change shape to lock the cover in place (such as a known unsafe-handling temperature). In some embodiments, the temperature threshold may be selected (such as by determining a physical makeup of the SMA material) based on the specific component or component type, on a material of the component, and the like. In one embodiment, the SMA material includes a copper-aluminum-nickel alloy. Depending on the makeup of the copper-aluminum-nickel alloy, the SMA material may exhibit transformation changes at temperatures ranging anywhere from −140 to 100 degrees Celsius. In another embodiment, the SMA material includes a nickel-titanium alloy. Depending on the makeup of the nickel-titanium alloy, the SMA material may exhibit transformation changes at temperatures ranging anywhere from −50 to 110 degrees Celsius. In another embodiment, the SMA material may include any other SMA alloy.

In the example of FIG. 1, the pin 103 is configured to change shape when the temperature of the SMA interlock (and the included pin 103) reaches or exceeds a temperature threshold specific to the SMA material of the SMA interlock. Because the SMA interlock 102 is thermally coupled to the component 100, the SMA interlock (namely, the pin 103) is configured to change shape back to it's configured ‘remembered’ shape when a temperature of the component 100 exceeds the temperature threshold. In the example of FIG. 1, the pin 103 is configured to interact with the cover 104. Specifically, the pin 103 is configured with a remembered shape that will cause the pin to engage with the loop 105 of the cover 104. For example, when a temperature of the component 100 of FIG. 1 exceeds the temperature threshold, the cover 104 will be locked in place (via the SMA interlock and its included pin 103) over the component, thereby preventing access to the component while it is above the temperature threshold.

The SMA material of the SMA interlock may be a ‘one-way’ or a ‘two-way’ shape memory alloy. A one-way SMA material can be deformed and then heated past its threshold temperature to change shape back to its remembered shape and will remain in that remembered shape after it has cooled until it is deformed again. For example, a pin 103 configured with a one-way SMA material will deform upon the cover 104 being positioned over the component (where the loop may cause the pin to bend down). Continuing with this example, the pin will change back to its remembered shape when the component heats up past the temperature threshold, causing the pin to lock the cover in place over the component. The pin will remain in the remembered shape, keeping the cover locked in place even after the component has cooled. Accordingly, removing the cover from the component would require an additional amount of force (enough to deform the pin). In such a way, a one-way SMA material in an SMA interlock would indicate to a user attempting to remove a cover that the underlying component may be too hot to handle.

A two-way SMA material has two different ‘remembered’ shapes—one at a first temperature threshold and a second at a second temperature threshold. The two remembered shapes may be configurable based on a heat treating process. For example, a two-way SMA interlock may be configured so that it disengages with the cover only when the component is cool enough to safely be handled (such as when the component is below the temperature threshold associated with the disengaging-remembered shape) and may also be configured to engage with the cover (locking it in place) only when the component is too hot to be safely handled (such as when the component is above the temperature threshold associated with the engaging-remembered shape). The two different temperature thresholds may be configurable based on a selection of the particular alloy used for the SMA material. In selecting the temperature thresholds, one can control at which temperatures a component is accessible. Preventing access to components that are too hot to be safely handled can prevent potential injuries or accidental damage to the component or other components in the system.

In one embodiment, there are multiple components with corresponding thermally coupled SMA interlocks. In such an embodiment, the threshold temperature for the SMA interlocks of each component are different from one another.

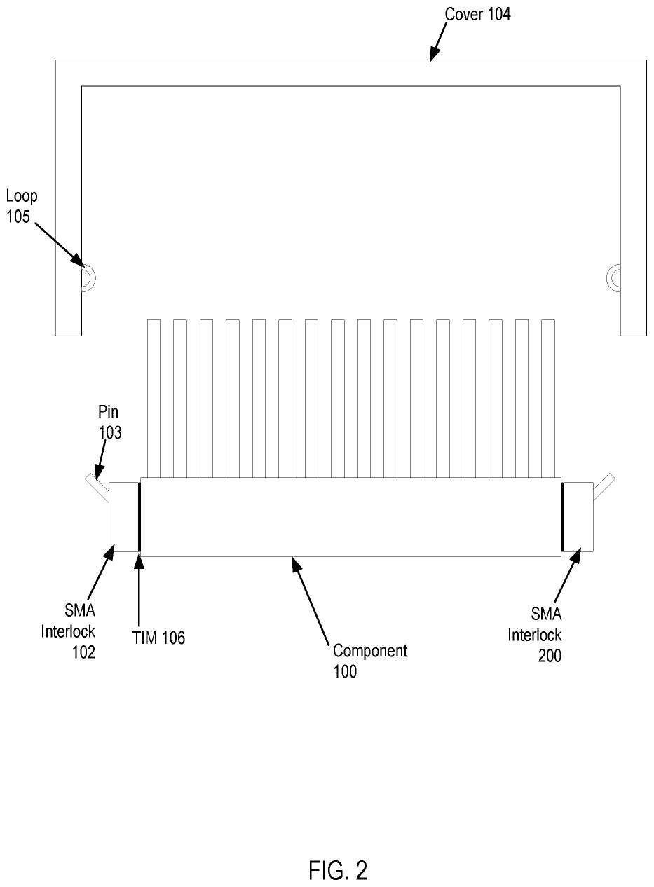

For further explanation, FIG. 2 sets forth another example line drawing of a system configured for blocking access to high temperature components in accordance with embodiments of the present disclosure. The example of FIG. 2 differs from FIG. 1 in that FIG. 2 shows the cover 104 lifted off of the component 100, allowing access to the component 100, and also includes another SMA interlock (SMA interlock 200) coupled to another surface of the component 100. In other embodiments, there may be additional SMA interlocks coupled to the component, such as on other sides of the component or multiple SMA interlocks on one or more sides of the component. Each SMA interlock is thermally coupled to the component.

The example of FIG. 2 shows the pin 103 of SMA interlock 102 (and SMA interlock 200) bent out of shape in comparison to the pin 103 of FIG. 1. In one embodiment, when the pin is composed of a two-way SMA material, the shape of the pin depicted in FIG. 1 (where the pin is engaged with the cover 104) may be a first remembered shape and the shape of the pin depicted here in FIG. 2 (where the pin is not engaged with the cover 104, allowing the cover to be removed) may be a second remembered shape. In such an example, each shape of the pin may correspond to a different temperature threshold. In another embodiment, when the pin is composed of a one-way SMA material, the shape of the pin depicted in FIG. 1 (where the pin is engaged with the cover 104) may be the remembered shape and the shape of the pin depicted here in FIG. 2 (where the pin is not engaged with the cover 104, allowing the cover to be removed) may be a result of the pin being deformed (such as by forcing the cover off of the component 100).

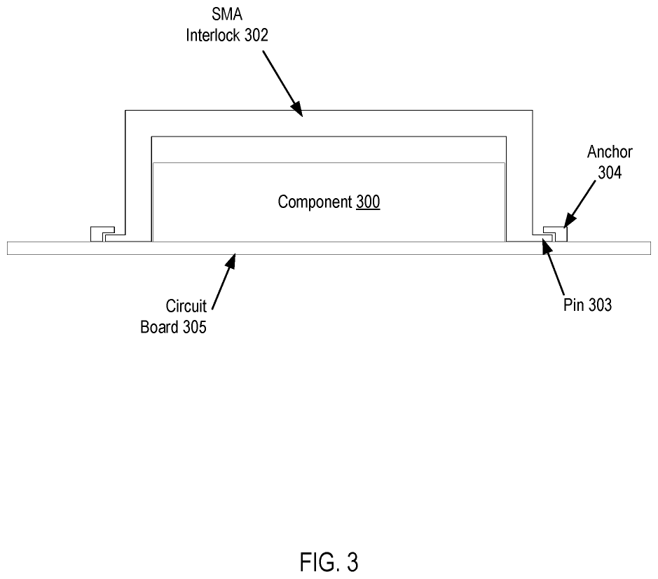

For further explanation, FIG. 3 sets forth another example line drawing of a system configured for blocking access to high temperature components in accordance with embodiments of the present disclosure. The example of FIG. 3 differs from FIG. 1 in that FIG. 3 shows the SMA interlock 302 configured as a cover positioned over the component 300. That is, rather than an SMA interlock coupled to a component that engages with a separate cover (as depicted in FIG. 1), the SMA interlock 302 of FIG. 3 is configured as a cover positioned over component 300 and is configured to change shape based on its temperature. The SMA interlock 302 is configured to be thermally coupled to the component 300. For example, the SMA interlock may contact one or more surfaces of the component 300 (as shown in FIG. 3). In another example, (not shown in FIG. 3) the portion of the SMA interlock covering the component may rest on the component. In one embodiment, a TIM is positioned between the SMA interlock and the component 300. In another embodiment, a thermal interface may be positioned on a surface outside of the component (such as on the circuit board 305) that is in thermal contact with both the SMA interlock and the component.

The SMA interlock 302 of FIG. 3 is configured to lock in place over the component to block access to the component when the component exceeds a temperature threshold. The component of FIG. 3 may include a semiconductor chip, computer memory, or any other computing component configured to be mounted on a circuit board or some other surface. The example SMA interlock 302 may be configured as a solid cover, a cover with holes for ventilation, a grate or grid allowing for airflow to the underlying component, or some other type of cover. In one embodiment, the SMA interlock 302 is configured to engage with anchors in order to keep the SMA interlock/cover in place over the component. In the example of FIG. 3, SMA interlock 302 includes one or more pins (pin 303) that are configured to engage with one or more anchors (anchor 304). In one embodiment the one or more pins are composed of an SMA material. In another embodiment, one or more other parts of the SMA interlock is composed of SMA material.

In the example system of FIG. 3, the anchors are mounted on a surface other than the component, such as circuit board 305. In another embodiment, the anchors may be mounted on the component or some other surface. In another embodiment, the SMA interlock may be configured to engage directly with the component itself (rather than anchors). In the example system of FIG. 3, the SMA interlock 302 is in the form of a cover. In another embodiment, the SMA interlock is separate from the cover (as shown in FIGS. 1 and 2) but is coupled to the cover, rather than to the component.

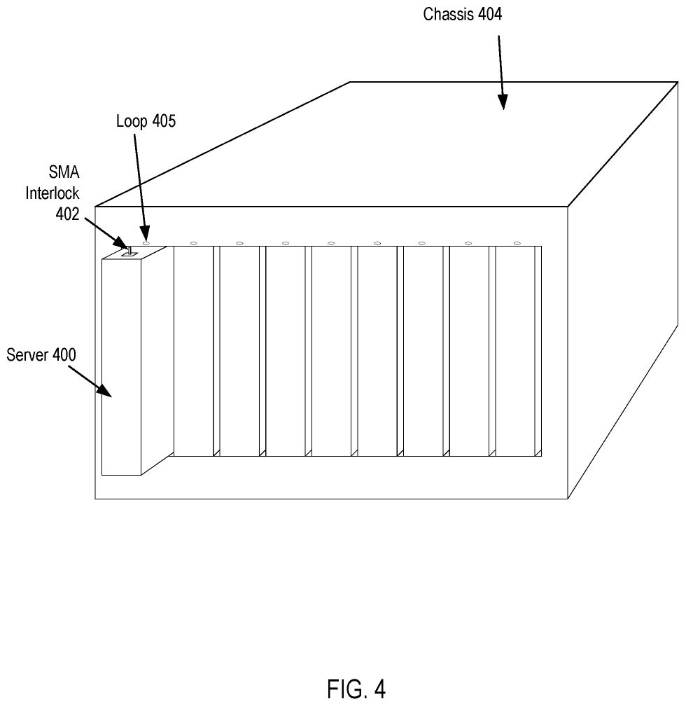

For further explanation, FIG. 4 sets forth another example line drawing of a system configured for blocking access to high temperature components in accordance with embodiments of the present disclosure. The example of FIG. 4 differs from FIG. 1 in that FIG. 4 shows the component as a server 400, such as a blade server, positioned in a chassis 404. Chassis 404 is configured to hold one or more servers or other computer components, such as server 400. Server 400 includes an SMA interlock 402 configured to lock the server in place, preventing a user from removing the server from the blade center. The chassis 404 of FIG. 4 includes one or more loops 405 configured to engage with the SMA interlock 402. In other embodiments, the blade center may include any other mechanism configured to engage the SMA interlock, such as a latch, hook, slot, hole, peg, and the like. The SMA interlock 402 includes one or more pins for engaging with the loop 405 of the blade center. In other embodiments, the SMA interlock may include any other mechanism configured to engage the blade center, such as a latch, slot, peg, hole, tab, and the like. In other embodiments, rather than a server 400, the component may be any other type of computing component, where the SMA interlock is configured to prevent the component from being removed (such as a server from a rack).

In view of the explanations set forth above, readers will recognize that the benefits of blocking access to high temperature components according to embodiments of the present disclosure include:
Decreasing the potential risk of injury when handling computer components, such as those that have become too hot to safely handle.
Adding protection to components when they are at high temperatures to prevent them from being damaged during handling.

Various aspects of the present disclosure are described by narrative text, flowcharts, and line drawings of cables. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A system for blocking access to high temperature components, the system comprising:
a computer component; and
a shape memory alloy (SMA) interlock thermally coupled to the computer component, wherein the SMA interlock is configured to prevent access to the computer component when a temperature of the computer component exceeds a threshold temperature.

2. The system of claim 1, further comprising a cover positioned over the computer component.

3. The system of claim 2, wherein the SMA interlock is configured to, when the temperature of the computer component exceeds the threshold temperature, lock the cover in place.

4. The system of claim 2, wherein the SMA interlock is configured to, when the temperature of the computer component falls below the threshold temperature, disengage from the cover.

5. The system of claim 1, wherein the SMA interlock is configured to allow access to the computer component when the temperature of the computer component falls below the threshold temperature.

6. The system of claim 1, wherein the SMA interlock comprises a copper aluminum nickel alloy.

7. The system of claim 1, wherein the SMA interlock comprises a nickel titanium alloy.

8. The system of claim 1, wherein the SMA interlock comprises a pin configured to expand when the temperature of the computer component exceeds the threshold temperature.

9. The system of claim 1, further comprising a thermal interface material (TIM) positioned between the computer component and the SMA interlock.

10. The system of claim 1, wherein the computer component comprises a heatsink.

11. The system of claim 1, wherein the computer component comprises a server.

12. The system of claim 1, further comprising a second computer component and a second SMA interlock thermally coupled to the second computer component, wherein the second SMA interlock is configured to prevent access to the second computer component when a temperature of the second computer component exceeds a second threshold temperature different from the threshold temperature.

13. The system of claim 1, wherein the threshold temperature is based on the computer component.

14. An apparatus for blocking access to high temperature components, the apparatus comprising:
a cover configured to block access to a computer component; and
an engaging component comprising a shape memory alloy (SMA) material, wherein the engaging component is configured to couple to the cover based on a temperature of the engaging component exceeding a threshold temperature.

15. The apparatus of claim 14, wherein coupling, by the engaging component, to the cover includes locking the cover in place, thereby preventing access to the computer component.

16. The apparatus of claim 14, wherein coupling, wherein the engaging component is configured to uncouple from the cover based on the temperature of the engaging component falling below the threshold temperature.

17. The apparatus of claim 14, wherein the engaging component comprises a pin configured to expand when the temperature of the engaging component exceeds the threshold temperature.

18. The apparatus of claim 14, wherein the SMA material comprises a copper aluminum nickel alloy.

19. The apparatus of claim 14, wherein the SMA material comprises a nickel titanium alloy.

20. The apparatus of claim 14, wherein the threshold temperature is based on the computer component.
